(19) United States
(12) Patent Application Publication
(10) Pub. No.: US 2004/0216908 A1
(43) Pub. Date: Nov. 4, 2004

(54) Woven shielded cable

(76) Inventor: Yi Huan Yen, Taichung (TW)

Correspondence Address: Yi Huan Yen, P.O. Box 63-298, Taichung, 406, TW

(21) Appl. No.: 10/755,057

(22) Filed: Jan. 7, 2004

(30) Foreign Application Priority Data
May 1, 2003 (TW) 092207051

(51) Int. Cl. H05K 9/00

(52) U.S. Cl. 174/35 C

(57) ABSTRACT

A woven shielded cable includes an insulation coat and one or more elongated conductor wires engaged within the insulation coat. A woven cover is engaged onto the insulation coat to isolate the elongated conductor wire from electromagnetic interference. The woven cover includes a number rows of wavy shaped strands interwoven together to define the woven cover, and to form a number of evenly distributed meshes for anti-electromagnetic purposes. A closure member may be engaged onto the insulation coat, and an outer protective sleeve may further be engaged onto the woven cover to form a closely protected woven shielded cable.

### BACKGROUND OF THE INVENTION

1. Field of the Invention

The present invention relates to a cable, and more particularly to a woven shielded cable having a woven cover to cover conductor wires and to shield the conductor wires against external electromagnetic interferences such as magnetic or radio frequency interference (RFI).

2. Description of the Prior Art

Typical electric cables comprise one or more elongated conductors engaged within or covered with a coating or insulation or with an insulated outer cover.

In electrical applications it is frequently desirable to shield the elongated conductors with various shielding members, against external electromagnetic interferences such as magnetic or radio frequency interference (RFI).

For example, U.S. Pat. No. 4,095,042 to Ross discloses one of the typical electric cables including a number of elongated conductor wires engaged within or covered with a woven cover which includes a number of metallic fiber strands interwoven together to define the woven cover and to isolate the conductor wires from electromagnetic interference.

However, the woven cover of the typical electric cables includes a number of fiber wrap strands, a number of metallic fill strands, and a number pairs of wrap binder strands, interwoven together, such that the manufacturing processes for the typical electric cables are complicated, and such that the manufacturing costs for the typical electric cables may not be decreased.

In addition, each of the elongated conductor wires may only be covered or shielded with a portion of the metallic fill strands; i.e., the elongated conductor wires may not be fully or completely covered or shielded with the metallic fill strands, such that the woven cover also may not be used to effectively shield and isolate the conductor wires from electromagnetic interference.

The present invention has arisen to mitigate and/or obviate the afore-described disadvantages of the conventional woven shielded cables.

### SUMMARY OF THE INVENTION

The primary objective of the present invention is to provide a woven shielded cable including a woven cover to cover conductor wires and to shield the conductor wires against external electromagnetic interferences such as magnetic or radio frequency interference (RFI).

In accordance with one aspect of the invention, there is provided a woven shielded cable comprising an insulation coat, at least one elongated conductor wire engaged within the insulation coat, and a woven cover engaged onto the insulation coat to isolate the elongated conductor wire from electromagnetic interference. The woven cover includes a number rows of wavy shaped strands interwoven together to define the woven cover, and to form a number of evenly distributed meshes therein, for anti-electromagnetic purposes.

Each of the strands is formed with a single thread having a wavy shape. The strands may all be formed with a single thread having an interwoven wavy shape.

A closure member may further be provided and engaged onto the insulation coat, and engaged within the woven cover. The closure member includes a number of peripheral bulges radially extended outwardly therefrom to form a number of peripheral recesses therein.

An outer protective sleeve may further be provided and engaged onto the woven cover to form a closely protected woven shielded cable.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a partial perspective view of a woven shielded cable in accordance with the present invention;

FIG. 2 is a partial exploded view of the woven shielded cable;

FIG. 3 is a partial cross sectional view of the woven shielded cable, taken along lines 3-3 of FIG. 1; and

FIG. 4 is an enlarged partial plan view illustrating a woven cover of the woven shielded cable.

### DETAILED DESCRIPTION OF THE PREFERRED EMBODIMENT

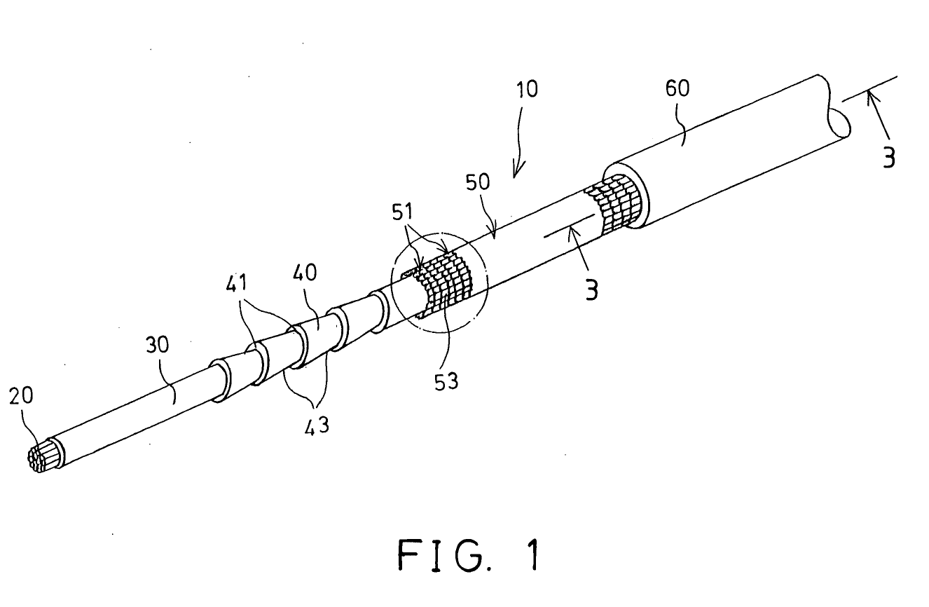

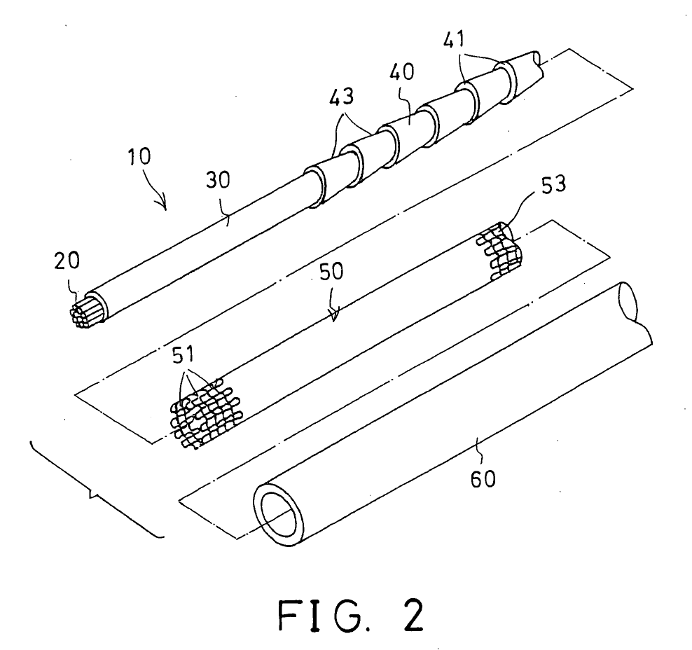

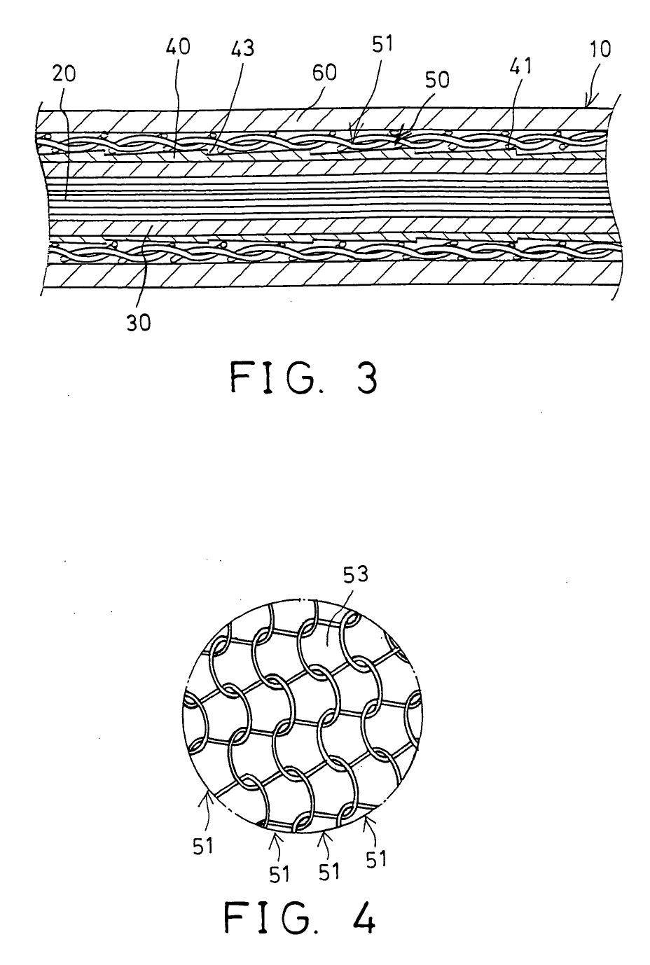

Referring to the drawings, and initially to FIGS. 1-3, a woven shielded cable 10 in accordance with the present invention is flexible and comprises one or more elongated conductor wires 20 engaged within or covered with a usual insulation coat 30 or the like that is typically made of rubber, plastic or other synthetic materials.

A closure member 40 may further be provided and engaged onto the insulation coat 30, and is preferably made of tin foil or the like, and includes a number of peripheral bulges 41 radially extended outwardly therefrom to form a number of peripheral recesses 43 therein.

A woven cover 50 is further provided and engaged onto the closure member 40, and includes an interwoven structure to isolate the conductor wires 20 from electromagnetic interference. An outer protective sleeve 60 may further be provided and engaged onto the woven cover 50 to form a closely covered or shielded or protected woven shielded cable 10.

As best shown in FIG. 4, the woven cover 50 includes one or more rows of wavy shaped strands 51 interwoven together to define the woven cover 50, and to form a number of orifices or meshes 53 therein, each of the strands 51 includes a wavy shape, and may be made of silver materials, copper materials, or other materials for such as anti-electromagnetic wave purposes.

In addition, each of the strands 51 may be formed with a single thread, and/or the strands 51 may also be formed or interwoven from the single thread or may be formed with a single thread having an interwoven wavy shape, for allowing the woven cover 50 to be easily and quickly manufactured or formed with a weaving or knitting machine (not shown), for mass production purposes.

It is to be noted that the rows of wavy shaped strands 51 are interwoven together to form a continuous or uniform structure or to form a number of evenly distributed meshes 53, to evenly engaged or wrapped around the conductor wires 20 and/or the insulation coat 30 and/or the closure member 40. Each of the evenly distributed meshes 53 includes a closed structure for further forming an anti-electromagnetic wave structure.

A test has been conducted to test the shielding effectiveness (SE) of the woven shielded cable 10 under different frequencies, in which SE=10 log (P2/P1), P1 is the output power, and P2 is the receiving power. The test result is listed as follows:

| Frequencies | SE | shielding percentage |
|---|---|---|
| 300 MHz | 21,245 dB | 99.25% |
| 900 MHz | 15,821 dB | 97.38% |
| 1.8 GHz | 17,013 dB | 98.01% |
| 2.45 GHz | 16,476 dB | 97.75% |

Accordingly, the woven shielded cable in accordance with the present invention includes a woven cover to cover conductor wires and to shield the conductor wires against external electromagnetic interferences such as magnetic or radio frequency interference (RFI).

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A woven shielded cable comprising:
an insulation coat, at least one elongated conductor wire engaged within said insulation coat, and
a woven cover engaged onto said insulation coat to isolate said at least one elongated conductor wire from electromagnetic interference,
said woven cover including a plurality rows of wavy shaped strands interwoven together to define said woven cover, and to form a plurality of evenly distributed meshes therein, for anti-electromagnetic purposes.

2. The woven shielded cable as claimed in claim 1, wherein each of said strands is formed with a single thread having a wavy shape.

3. The woven shielded cable as claimed in claim 1, wherein said strands are formed with a single wavy shaped thread.

4. The woven shielded cable as claimed in claim 1 further comprising a closure member engaged onto said insulation coat, and engaged within said woven cover.

5. The woven shielded cable as claimed in claim 4, wherein said closure member includes a plurality of peripheral bulges radially extended outwardly therefrom to form a plurality of peripheral recesses therein.

6. The woven shielded cable as claimed in claim 1 further comprising an outer protective sleeve engaged onto said woven cover to form a closely protected woven shielded cable.
